(19) United States
(12) Patent Application Publication
(10) Pub. No.: US 2014/0332052 A1
(43) Pub. Date: Nov. 13, 2014

(54) SOLAR POWER SYSTEM WITH CLIMATE CONTROL AND METHOD THEREOF

(71) Applicants: Daniel S. Yacoubian, Burbank, CA (US); Stephan V. Yacoubian, Burbank, CA (US)

(72) Inventors: Daniel S. Yacoubian, Burbank, CA (US); Stephan V. Yacoubian, Burbank, CA (US)

(21) Appl. No.: 14/275,530

(22) Filed: May 12, 2014

Related U.S. Application Data
(60) Provisional application No. 61/821,797, filed on May 10, 2013.

(51) Int. Cl. H01L 31/052

(52) U.S. Cl. CPC H01L 31/0521
USPC 136/246

(57) ABSTRACT

A system and method configured to increase electric output of solar power via at least one solar panel by directing forced air from an air-conditioning condenser unit to the solar panel, thereby reducing the temperature of the solar panel.

### CROSS-REFERENCE TO RELATED APPLICATION

This patent application claims priority to U.S. Provisional Patent Application Ser. No. 61/821,797 titled SOLAR POWER SYSTEM WITH CLIMATE CONTROL AND METHOD THEREOF, and filed May 10, 2013, the entire content of which is incorporated by reference in its entirety.

### BACKGROUND

1. Field

The present inventive concept pertains to a system and method of generating and outputting solar power. The present inventive concept more particularly concerns a system and method configured to increase electric output of solar power via at least one solar panel by directing forced air from an air-conditioning unit to the solar panel, thereby reducing the temperature of the solar panel.

2. Discussion of Related Art

Solar panels function to convert energy contained within the sun's rays to electricity. To capture the energy from the sun's rays, it is necessary that the solar panels be exposed to the sun. Thus, when the solar panels are functioning to produce electricity, the solar panels are being heated by the sun, which causes a thin layer of heat to form and rest on an upper surface of the solar panels. The thin layer of heat on the upper surface of the solar panels causes a rise in temperature of the solar panels, which causes a quantifiable decrease in production of the electricity by the solar panels. Thus, a cool and sunny day presents an ideal condition for optimal production of electricity by the solar panels. Such days, however, are few and far between in most climates.

Thus, there is a need for a solar power generation system that does not suffer from the aforementioned problems, and provides optimal energy output despite exposure to sun with minimal or no increase in energy expended, is inexpensive to manufacture and purchase, and easy to install.

### SUMMARY

The present inventive concept described herein remedies the aforementioned problems by providing a system and method configured to produce or increase production of solar power via at least one solar panel by directing forced air from an air-conditioning unit to the solar panel, thereby reducing the temperature of the solar panel.

The present inventive concept provides a system and method operable to cause a temperature of a solar panel of a solar-power generating system to be reduced. The system utilizes a retrofit apparatus having a mount configured to securely connect to a preexisting air conditioning condenser, e.g., of a commercial and/or residential structure or vehicle, so that exhaust generated by the condenser is at least partially captured by the retrofit apparatus and directed to a surface of a solar panel mounted adjacent thereto by the retrofit apparatus. It is foreseen that the solar panel may at least partially power the condenser and/or a battery connected to the condenser.

This present inventive concept provides utilizes an air tubing apparatus which redirects forced air, produced by an outdoor air conditioning condenser, to one or more solar panels. The tubing apparatus of the present inventive concept is operable to redirect airflow to the solar panel and decrease its temperature significantly, thus increasing electric output. Specifically, upon measurement of electric output of an experimental solar panel receiving redirected airflow using the present inventive concept as compared to a control solar panel's output receiving no airflow from the air conditioning condenser, it was discovered that there was at least an eight percent (8%) increase in the experimental solar panel voltage output when the present inventive concept employed with the air conditioning condenser unit, i.e., when the air conditioner was activated. In this manner, the experimental solar panel produced more electricity compared to the control because the present inventive concept successfully decreased the temperature of the panel.

This present inventive concept provides an energy neutral system and method operable to improve solar panel output, e.g., during warm weather when a climate control system e.g., an air conditioning system, is in use with a residential or commercial structure. The system and method of the present inventive concept require no extra energy other than that already being expended for and produced by a preexisting air conditioning condenser.

This present inventive concept is operable to improve output of solar panels in a solar system by cooling the panels, e.g., when they are hot, of a residential or commercial structure. The cooling of the panels is accomplished by the present inventive concept by providing airflow over the solar units, e.g., at least one surface of the solar unit, e.g., exposed to the sun, and/or a heat and/or light source. This airflow is produced by expending no extra energy and, therefore, is energy-neutral for the system using the air conditioning condenser of the air conditioner. Typical air conditioning condensers produce exhaust in the form of a powerful stream of air, which is exhausted outdoors into the atmosphere. The system and method of the present inventive concept utilizes various components, e.g., a harness adapted to mate with the air conditioner, piping adapted to pipe the exhaust from the air conditioning condenser to one or more solar panels, and a nozzle adapted to distribute the exhaust from the piping and to the solar panel. In this manner, the system and method of the present inventive concept utilizes previously lost or otherwise unused airflow to increase energy production of a solar power energy production system.

It is foreseen that the system and method of the present inventive concept may utilize insulated tubing as the piping. It is foreseen that the nozzle may be configured to direct exhaust to blow off and otherwise remove a heat layer residing on top of one or more of the panels, which causes the panels to be cooled. It is foreseen that the exhaust may also act to cool other areas of the solar panel.

It is foreseen that the ideal time for use of the present inventive concept is the warmest part of the day when (i) hot solar panels have compromised electric output, and (ii) the air conditioning system is running to cool the house for the occupants during the warmest part of the day. It is foreseen that the present inventive concept is only used when an air conditioning unit is activated to cool an interior and not any other time, i.e., the air conditioning unit is not activated solely for the purpose of cooling one or more of the solar panels. The airflow produced by the AC condenser is simply a beneficial by-product of cooling the house and is harnessed and redirected via use of the apparatus and method of the present inventive concept to increase energy production of the solar panels. Via use of the apparatus and method of the present inventive concept, cost of cooling a home in hot summer months will be partially offset by higher energy production.

The aforementioned may be achieved in an aspect of the present inventive concept by providing a retrofit system for an air conditioning system and a solar power generation system. The retrofit system may include a harness adapted to be secured to an exhaust outlet of the air conditioning system. The harness may have openings in lowermost and uppermost ends thereof. The lowermost opening may be to at least partially cover the exhaust outlet. The retrofit system may further include at least one nozzle configured to (i) receive air from the harness, and/or (i) direct air to at least a portion of the solar power generation system. The retrofit system may further include a conduit having (i) a first end secured to the uppermost opening of the harness so that the uppermost opening is completely covered, and/or (ii) a second end secured to the nozzle.

The solar power generation system may be operable to at least partially power the air conditioning system. The portion of the solar power generation system may be at least one solar panel. The nozzle may be configured to direct air expelled therefrom to and/or across an uppermost surface of the at least one solar panel of the solar power generation system.

The second end of the conduit may be split into a plurality of conduits. Each of the plurality of conduits may have a nozzle or any other opening without deviating from the scope of the present inventive concept. Each of the nozzles may be configured to direct air expelled therefrom to and/or across one or more surfaces, e.g., an uppermost surface, of the at least one solar panel of the solar power generation system. Each of the nozzles may be positioned (i) partially around a perimeter of the at least one solar panel, and/or (ii) entirely around the perimeter of the at least one solar panel. Each of the nozzles may be positioned (i) along one side of the at least one solar panel, (ii) along two sides of the at least one solar panel, (iii) along three sides of the at least one solar panel, and/or (iv) along four sides of the at least one solar panel.

The lowermost opening of the harness may be larger than the uppermost opening of the harness. The conduit may be spaced from the exhaust outlet of the air conditioning system by the harness. The exhaust outlet of the air conditioning system may receive air from an air conditioning condenser.

The aforementioned may be achieved in another aspect of the present inventive concept by providing a method of improving efficiency of a solar power generation system using an air conditioning system. The method may include the step of securing a harness to an exhaust outlet of the air conditioning system. The harness may have openings in lowermost and uppermost ends thereof. The lowermost opening may be secured to at least partially cover the exhaust outlet. The method may further include the steps of attaching an air conduit having a first end secured to the uppermost opening of the harness so that the uppermost opening is completely covered, and/or positioning a second end of the air conduit so as to direct air received through the air conduit to at least a portion of the solar power generation system.

The method may include the step attaching at least one nozzle to the second end of the air conduit so as to direct air to the portion of the solar power generation system. The solar power generation system may be operable to at least partially power the air conditioning system. The portion of the solar power generation system may be at least one solar panel. The nozzle may be configured to direct air expelled therefrom to and/or across an uppermost surface of the at least one solar panel of the solar power generation system.

The second end of the conduit may split the conduit into and/or form a plurality of conduits. Each of the plurality of conduits may have a nozzle. Each of the nozzles may be configured to direct air expelled therefrom to and/or across an uppermost surface of the at least one solar panel of the solar power generation system. Each of the nozzles may be positioned (i) partially around a perimeter of the at least one solar panel, and/or (ii) entirely around the perimeter of the at least one solar panel. Each of the nozzles may be positioned (i) along one side of the at least one solar panel, (ii) along two sides of the at least one solar panel, (iii) along three sides of the at least one solar panel, and/or (iv) along four sides of the at least one solar panel.

The lowermost opening of the harness may be larger than the uppermost opening of the harness. The conduit may be spaced from the exhaust outlet of the air conditioning system by the harness. The exhaust outlet of the air conditioning system may receive air from an air conditioning condenser.

The aforementioned may be achieved in another aspect of the present inventive concept by providing an air conditioning and solar power generation system. The system may include a harness adapted to be secured to an exhaust outlet of an air conditioning condenser of the system. The harness may have openings in lowermost and uppermost ends thereof. The lowermost opening may be secured to at least partially cover the exhaust outlet. The system may further include at least one nozzle configured to (i) receive air from the harness, and (i) direct air to at least one solar panel of the system. The system may further include a conduit having (i) a first end secured to the uppermost opening of the harness so that the uppermost opening is completely covered, and (ii) a second end secured to the nozzle.

Additional objectives, aspects, advantages, and utilities of the present inventive concept will be set forth in part in the description which follows and, in part, will be obvious from the description, or may be learned by practice of the present inventive concept.

The foregoing is intended to be illustrative and is not meant in a limiting sense. Many features and subcombinations of the present inventive concept may be made and will be readily evident upon a study of the following specification and accompanying drawings comprising a part thereof. These features and subcombinations may be employed without reference to other features and subcombinations.

### BRIEF DESCRIPTION OF THE DRAWINGS

The present inventive concept is described in detail below with reference to the attached drawing FIGURE, wherein:

FIG. 1 illustrates a system of the present inventive concept.

The drawing FIGURE does not limit the present inventive concept to the specific examples disclosed and described herein. The drawing FIGURE is not necessarily to scale, emphasis instead being placed upon clearly illustrating the principles of the present inventive concept.

### DETAILED DESCRIPTION

The following detailed description references the accompanying drawings that illustrate the present inventive concept. The illustrations and description are intended to describe aspects of the present inventive concept in sufficient detail to enable those skilled in the art to practice the present inventive concept. Other components can be utilized and changes can be made without departing from the scope of the present inventive concept. The following detailed description is, therefore, not to be taken in a limiting sense. The scope of the present inventive concept is defined only by the appended claims, along with the full scope of equivalents to which such claims are entitled.

In this description, references to “one embodiment,” “an embodiment,” or “embodiments” mean that the feature or features being referred to are included in at least one embodiment of the present inventive concept. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present inventive concept can include a variety of combinations and/or integrations of the embodiments described herein.

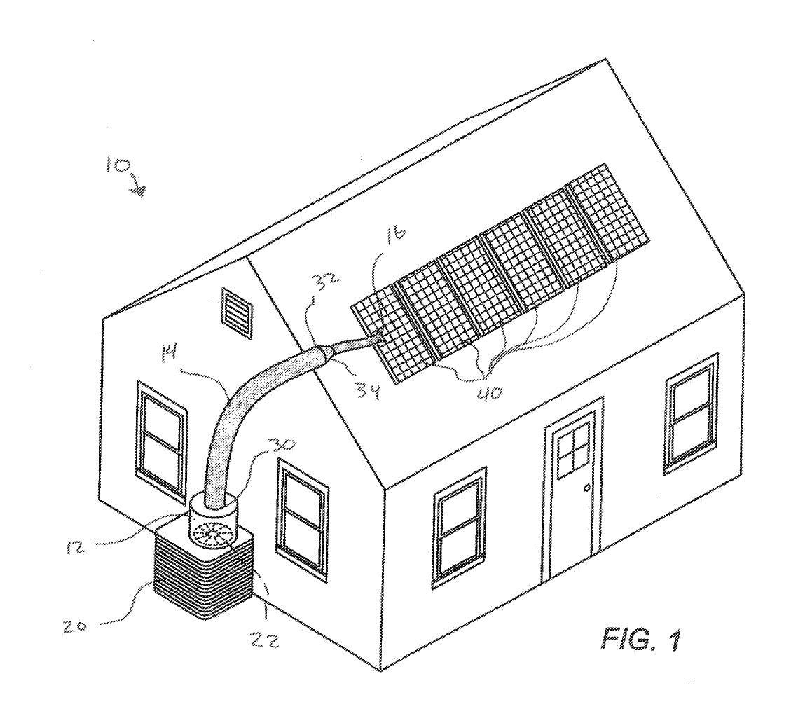

Turning to FIG. 1, a solar power generating and cooling system 10 of the present inventive concept is illustrated. The system 10 generally includes a harness 12, an air-delivery conduit 14, and a nozzle 16. The harness 12 is configured to be retrofit to and securely engaged to a preexisting air conditioning condenser 20 of an air conditioning unit configured to provide climate control for a commercial or residential structure and/or a vehicle. It is foreseen that the air conditioning condenser 20 may be simultaneously manufactured to be a part of and installed simultaneously with the system 10.

The harness 12 is mounted to at least partially cover an exhaust vent 22 of the air conditioning condenser 20. It is foreseen that the harness 12 may entirely cover and be sealed to an entirety of the exhaust vent 22 so as to capture all air exhausted from the exhaust vent 22 or be spaced from the exhaust vent 22 so as to capture a majority of air exhausted from the exhaust vent 22 in combination with other, cooler air not exhausted from the exhaust vent 22, thereby causing air traveling through the harness 12 to be cooler without deviating from the scope of the present inventive concept. In the illustrated embodiment, the exhaust vent 22 is located at an uppermost side of the air conditioning condenser 20 based on an orientation of the exhaust vent 22 with respect to the air condenser 20 in the illustrated embodiment. It is foreseen that the harness 12 can be located on any side of the air condition condenser 20 as long as the harness 12 covers at least a portion of the exhaust vent 22 without deviating from the scope of the present inventive concept. The harness 12 is secured to the uppermost side of the air conditioning condenser 20 via at least one fastener, e.g., a nut and bolt combination or the like. The harness 12 has a solid cylindrical outer wall, and a partially solid flat uppermost surface with an aperture in a center thereof. The harness 12 has a mouth at a lowermost portion of the outer wall, which is sized and shaped to at least partially cover the exhaust vent 22. It is foreseen that the harness 12 may be conical so as to be operable to funnel air from the exhaust vent 22, which has a larger diameter to the air-delivery conduit 14, which has a relatively smaller diameter than the exhaust vent 22 in which case the uppermost surface may be omitted so that each end of the harness 12 has a mouth of different diameters. It is foreseen that the material of the air-delivery conduit 14 not be insulated or at least minimally insulated so as to allow air to cool when the air travels through the air-delivery conduit 14 without deviating from the scope of the present inventive concept.

The air-delivery conduit 14 is securely engaged to the harness 12 via a friction fit engagement, an adhesive, at least one fastener, and/or the like so that the air-delivery conduit 14 completely covers and conceals the aperture of the harness 12. In the exemplary embodiment, the air-delivery conduit 14 is an insulated elongated pipe made of a flexible material that permits expansion and retraction of the air-delivery conduit 14 so as to facilitate use of the system 10 in various applications.

The air-delivery conduit 14 includes a first section 30 and a second section 32. The first section 30 is on a side of the air-delivery conduit 14 that is engaged to the harness 12, and has a larger diameter than that of the second section 32. A conical mating section 34 securely engages the sections 30, 32 to each other via a friction fit engagement, an adhesive, at least one fastener, and/or the like and provides a transition between the different diameters. It is foreseen that the conical mating section 34 may include securing means so as to permit secure engagement to a surface element of the structure or vehicle so as to further secure the system 10 thereto.

The second section 32 is securely engaged to the nozzle 16 via a friction fit engagement, an adhesive, at least one fastener, and/or the like. In this manner, the sections 30, 32, 34 form an air passage that begins at the harness 12, extends through the sections 30, 32, 34, and terminates at the nozzle 16. The decreasing diameters of the sections 30, 32, 34 advantageously causes increased air pressure as air travels along the sections 30, 32, 34 and is exhausted from the nozzle 16. The nozzle 16 is configured to direct the air exhausted therefrom to a desired, predetermined location.

In the exemplary embodiment, the nozzle 16 is positioned via a mount or the like so that the air exhausted from the nozzle 16 travels over an uppermost surface of at least one preexisting solar panel 40 of a solar power generation system configured to provide solar power to the commercial or residential structure and/or the vehicle. It is foreseen that the solar panel 40 may be a part of and installed simultaneously with the system 10.

In this manner, the air exhausted from the nozzle 16 moves any hot air, e.g., a layer of hot air that may reside on the solar panel 40 during an optimum solar power collection time of day, off and/or away from the uppermost surface of the solar panel 40. The movement of the air off and/or away from the uppermost surface of the solar panel 40 causes the solar panel 40 to be cooled. The air exhausted from the nozzle 16 is lower in temperature than the layer of hot air that may reside on the solar panel 40 and/or the solar panel 40 itself. Thus, the air exhausted from the air-conditioning condenser 20 is operable to cool the solar panel 40.

Testing results derived from use of the system 10 of the present inventive concept demonstrate that by delivering airflow from the air-conditioning condenser 20 to the solar panel 40 of the system 10, voltage output of the solar panel 40 is increased by at least 8%. Furthermore, this increased efficiency is achieved without adding any additional energy into the system 10 that is not already required for use, i.e., in the instance that the air conditioning condenser 20 is preexisting and already running to cool and provide desired climate control for the structure or the vehicle, no additional energy is required to pipe exhaust from the air conditioning condenser 20 to the solar panel 40. An 8% increase in the production of power by a solar energy system of the solar panel 40 can equal a considerable dollar savings as well as conservation of energy production by a power supplier.

The test data results demonstrate a relationship between temperature and voltage production, i.e., as temperature decreases, solar voltage production of the solar panel 40 increases. It is noted that although the air conditioning condenser 20 exhausts warm air from the structure or vehicle, the exhausted air is not typically as warm as the heat film that may reside on the solar panel 40, which may reach upwards of 130 degrees F. Indeed, the warm air from the air conditioning condenser 20 typically measures at a temperature of around 78 F, which therefore has a significant cooling effect on the solar panel 40 as demonstrated by the graphs.

The test data results were obtained in a climate of Palm Desert, Calif. during clear sunny days of winter. The ambient air temperature during the experiment was in the low 60's F, and the solar panel temperatures rose steadily into the low 130s F. During the summertime however, ambient air temperatures can reach into the 120's F and the solar panel 40 temperatures into the 150's F and beyond. At these higher temperatures, the efficiency of solar energy production would be more compromised than during winter time and the air conditioning system would certainly be in demand. It is under these latter conditions that the system 10 is most useful. At higher temperatures, it is foreseen that the increase in voltage production by cooling the solar panel 40 may exceed the 8% increase in voltage.

It is foreseen that the nozzle 16 may be shaped and/or sized to deliver air and cool any number and/or sized versions of the solar panel 40. For instance, It is foreseen that the nozzle 16 may be elongated and/or the conduit 14 may include a splitter, e.g., at an end of the nozzle 16, with multiple sections, channels, and/or openings each with a nozzle 16 to each cool one or more different sections or portions of the solar panel 40 and or different ones of the solar panel 40. It is foreseen that the multiple sections of the conduit 14 may include a longer and/or thinner, e.g., diameter, tubing system with multiple openings that can run along the periphery, e.g., surround one, two, three or all sides, of each of the solar panel 40 and deliver air towards the center of each of the solar panel 40.

The previous description of the presently disclosed inventive concept is provided to enable any person skilled in the art to make or use the present inventive concept. Various modifications will be readily apparent to those skilled in the art, and the generic principles defined herein may be applied alternatively without departing from the spirit or scope of the present inventive concept. Thus, the present inventive concept is not intended to be limited to the description herein but is to be accorded the widest scope consistent with the principles and novel features disclosed herein.

Having now described the features, discoveries and principles of the present inventive aspect of this disclosure, the manner in which the present inventive aspect is constructed and used, the characteristics of the construction, and advantageous, new and useful results obtained; the new and useful structures, devices, elements, arrangements, parts and combinations, are set forth in the appended claims.

It is also to be understood that the following claims are intended to cover all of the generic and specific features of the present inventive aspect herein described, and all statements of the scope of the present inventive aspect which, as a matter of language, might be said to fall there between.

What is claimed is:

1. A retrofit system for an air conditioning system and a solar power generation system, the retrofit system comprising:
a harness adapted to be secured to an exhaust outlet of the air conditioning system, the harness having openings in lowermost and uppermost ends thereof, the lowermost opening secured to at least partially cover the exhaust outlet; and
at least one nozzle configured to (i) receive air from the harness, and (i) direct air to at least a portion of the solar power generation system; and
a conduit having (i) a first end secured to the uppermost opening of the harness so that the uppermost opening is completely covered, and (ii) a second end secured to the nozzle.

2. The retrofit system according to claim 1, wherein the solar power generation system is operable to at least partially power the air conditioning system.

3. The retrofit system according to claim 1, wherein the portion of the solar power generation system is at least one solar panel.

4. The retrofit system according to claim 3, wherein the nozzle is configured to direct air expelled therefrom to and/or across an uppermost surface of the at least one solar panel of the solar power generation system.

5. The retrofit system according to claim 3, wherein the second end of the conduit splits into a plurality of conduits, each of the plurality of conduits having a nozzle.

6. The retrofit system according to claim 3, wherein each of the nozzles are configured to direct air expelled therefrom to and/or across an uppermost surface of the at least one solar panel of the solar power generation system.

7. The retrofit system according to claim 6, wherein each of the nozzles are positioned (i) partially around a perimeter of the at least one solar panel, or (ii) entirely around the perimeter of the at least one solar panel.

8. The retrofit system according to claim 6, wherein each of the nozzles are positioned (i) along one side of the at least one solar panel, (ii) along two sides of the at least one solar panel, (iii) along three sides of the at least one solar panel, or (iv) along four sides of the at least one solar panel.

9. The retrofit system according to claim 1, wherein the lowermost opening of the harness is larger than the uppermost opening of the harness.

10. The retrofit system according to claim 1, wherein the conduit is spaced from the exhaust outlet of the air conditioning system by the harness.

11. The retrofit system according to claim 1, wherein the exhaust outlet of the air conditioning system receives air from an air conditioning condenser.

12. A method of improving efficiency of a solar power generation system using an air conditioning system, the method comprising the steps of:
securing a harness to an exhaust outlet of the air conditioning system, the harness having openings in lowermost and uppermost ends thereof, the lowermost opening secured to at least partially cover the exhaust outlet; and
attaching an air conduit having a first end secured to the uppermost opening of the harness so that the uppermost opening is completely covered; and
positioning a second end of the air conduit so as to direct air received through the air conduit to at least a portion of the solar power generation system.

13. The method according to claim 12, further comprising the step of:
attaching at least one nozzle to the second end of the air conduit so as to direct air to the portion of the solar power generation system.

14. The retrofit system according to claim 12, wherein the solar power generation system is operable to at least partially power the air conditioning system.

15. The retrofit system according to claim 12, wherein the portion of the solar power generation system is at least one solar panel.

16. The retrofit system according to claim 15, wherein the nozzle is configured to direct air expelled therefrom to and/or across an uppermost surface of the at least one solar panel of the solar power generation system.

17. The retrofit system according to claim 15, wherein the second end of the conduit splits into a plurality of conduits, each of the plurality of conduits having a nozzle.

18. The retrofit system according to claim 15, wherein each of the nozzles are configured to direct air expelled therefrom to and/or across an uppermost surface of the at least one solar panel of the solar power generation system.

19. The retrofit system according to claim 18, wherein each of the nozzles are positioned (i) partially around a perimeter of the at least one solar panel, or (ii) entirely around the perimeter of the at least one solar panel.

20. The retrofit system according to claim 18, wherein each of the nozzles are positioned (i) along one side of the at least one solar panel, (ii) along two sides of the at least one solar panel, (iii) along three sides of the at least one solar panel, or (iv) along four sides of the at least one solar panel.

21. The retrofit system according to claim 12, wherein the lowermost opening of the harness is larger than the uppermost opening of the harness.

22. The retrofit system according to claim 12, wherein the conduit is spaced from the exhaust outlet of the air conditioning system by the harness.

23. The retrofit system according to claim 12, wherein the exhaust outlet of the air conditioning system received air from an air conditioning condenser.

24. An air conditioning and solar power generation system comprising:
a harness adapted to be secured to an exhaust outlet of an air conditioning condenser of the system, the harness having openings in lowermost and uppermost ends thereof, the lowermost opening secured to at least partially cover the exhaust outlet; and
at least one nozzle configured to (i) receive air from the harness, and (i) direct air to at least one solar panel of the system; and
a conduit having (i) a first end secured to the uppermost opening of the harness so that the uppermost opening is completely covered, and (ii) a second end secured to the nozzle.
